(19) United States
(12) Patent Application Publication
(10) Pub. No.: US 2025/0040423 A1
(43) Pub. Date: Jan. 30, 2025

(54) NOVEL COMPOUNDS

(71) Applicants: OXFORD UNIVERSITY INNOVATION LIMITED, Oxford (GB); KING ABDULLAH UNIVERSITY OF SCIENCE AND TECHNOLOGY (KAUST), Thuwal (SA); FLEXENABLE TECHNOLOGY LTD, Cambridge (GB)

(72) Inventors: Iain MCCULLOCH, Oxford (GB); Hu CHEN, Thuwal (SA); Helen BRISTOW, Oxford (GB); Yoann PORTE, Cambridge (GB); Patrick TOO, Cambridge (GB)

(21) Appl. No.: 18/716,180

(22) PCT Filed: Dec. 6, 2022
(86) PCT No.: PCT/GB2022/053102

§ 371 Date: Jun. 4, 2024

(30) Foreign Application Priority Data
Dec. 6, 2021 (GB) 2117608.6

(51) Int. Cl. H10K 85/10; C08G 61/12; H10K 10/46

(52) U.S. Cl. CPC H10K 85/113; C08G 61/126; C08G 2261/124; C08G 2261/1412; C08G 2261/3243; C08G 2261/3247; C08G 2261/414; C08G 2261/92; H10K 10/464

(57) ABSTRACT

Novel compounds comprising x-conjugated moicties are disclosed, as well as their uses as semiconducting materials. The novel compounds comprise adjacent x-electron rich and x-electron deficient moieties. The novel compounds exhibit improved charge mobility and are particularly suited to use in electronic devices and components, such as organic thin film transistors.

### INTRODUCTION

The present invention relates to novel compounds (e.g. polymers) comprising π-conjugated moieties, as well as to their use as semiconducting materials. More particularly, the present invention relates to novel compounds comprising adjacent π-electron rich and π-electron deficient moieties (e.g. donor-acceptor copolymers), as well as their use in electronic devices and components.

### BACKGROUND OF THE INVENTION

Over the past three decades, significant effort has been devoted to the development of organic thin film transistors (OTFTs) based on π-conjugated organic semiconductors, paving the way for the next the generation of solution-processed electronics for logic circuits as well as lightweight and flexible displays.^{[1.2]} Advances in polymer design for OTFTs have largely been driven by the necessity to achieve high mobilities. Mobilities exceeding 1 cm²V⁻¹ s⁻¹ have been achieved as a result of a better understanding of the structure-performance relationships of π-conjugated organic semiconductors which has directed the rational design and synthesis of new polymers.^{[3-5]} Early OTFT polymer development was focused on homopolymers, which exhibited a high degree of crystallinity in thin films. These polymer films exhibit long-range structural order which promotes charge-transport between polymer chains and thereby leads to high charge carrier mobilities in the bulk material.^{[6.7]} Charge-transport in this type of material is both intramolecular, along the backbone, and intermolecular, in the π-TT stacking direction. More recent research has been concentrated on donor-acceptor (D-A) copolymers, in which transport along the conjugated backbone is the major contributor to charge-transport. These polymers, such as indaceno [1,2-b:5,6-b′] dithiophene-co-2, 1,3-benzothiadiazole (IDT-BT) and DPP-BTz, exhibit comparatively amorphous microstructures in thin films, whilst also delivering mobilities over 1 cm²V⁻¹ s⁻¹.^{[8-11]} It has been shown that such D-A polymers owe their high mobilities to very low energetic disorder, which is associated with a uniform distribution of different polymer conformations within the thin films.^{[6,12]}

Several design strategies have been employed to optimise the mobility of D-A copolymers including extending the donor unit, modifying the acceptor unit and varying substituents such as alkyl groups on the donor unit.^{[4.5.13.14]} However, in only a few cases were these modifications successful in charge-carrier mobility.^{[3-5]}

The present invention was devised with the foregoing in mind.

### SUMMARY OF THE INVENTION

According to a first aspect of the present invention there is provided a compound comprising a unit of formula (I) defined herein.

Suitably, the compound is a polymer or oligomer comprising a repeating unit of formula (I) (e.g. a donor-acceptor copolymer).

According to a second aspect of the present invention there is provided an electronic device or component comprising a compound of the first aspect.

Suitably the electronic device or component is an organic thin film transistor.

According to a third aspect of the present invention there is provided a use of a polymer or oligomer defined herein as a semiconducting material.

### DETAILED DESCRIPTION OF THE INVENTION

The term “(m-nC)” or “(m-nC) group” used alone or as a prefix, refers to any group having m to n carbon atoms.

The term “alkyl” as used herein refers to straight or branched chain alkyl moieties. When used as a substituent on D, alkyl moieties may, for example, have 1, 2, 3 or 4 carbon atoms. When used as a substituent on A, alkyl moieties may be significantly longer, having, for example, up to 30 carbons (e.g. 8-20 carbons).

The term “alkenyl” as used herein refers to straight or branched chain alkenyl moieties (including both the cis and trans isomers thereof). When used as a substituent on D, alkenyl moieties may, for example, have 1, 2, 3 or 4 carbon atoms. When used as a substituent on A, alkenyl moieties may be significantly longer, having, for example, up to 30 carbons (e.g. 8-20 carbons).

The term “alkynyl” as used herein refers to straight or branched chain alkynyl moieties. When used as a substituent on D, alkynyl moieties may, for example, have 1, 2, 3 or 4 carbon atoms. When used as a substituent on A, alkynyl moieties may be significantly longer, having, for example, up to 30 carbons (e.g. 8-20 carbons).

The term “alkoxy” as used herein refers to-O-alkyl, wherein alkyl is straight or branched chain and typically comprises 1, 2, 3, 4, 5 or 6 carbon atoms. This term includes reference to groups such as methoxy, ethoxy, propoxy, isopropoxy, butoxy, tert-butoxy, pentoxy, hexoxy and the like. Often, alkoxy is methoxy.

The term “aromatic” as used herein means an aromatic ring system comprising 6, 7, 8, 9 or 10 ring carbon atoms. A particularly suitable aromatic ring is benzene.

The term “heteroaromatic” means an aromatic ring incorporating one or more (for example 1-4, particularly 1, 2 or 3) heteroatoms selected from nitrogen, oxygen and sulfur. The heteroaromatic ring can be a 5-or 6-membered ring. Typically, the heteroaromatic ring will contain up to 3 heteroatoms (e.g. nitrogen), more usually up to 2, for example a single heteroatom.

The term “halo” as used herein refers to F, Cl, Br or I.

The term “substituted” as used herein in reference to a moiety means that one or more, especially up to 5, more especially 1, 2 or 3, of the hydrogen atoms in said moiety are replaced independently of each other by the corresponding number of the described substituents. The term “optionally substituted” as used herein means substituted or unsubstituted.

It will, of course, be understood that substituents are only at positions where they are chemically possible, the person skilled in the art being able to decide (either experimentally or theoretically) without inappropriate effort whether a particular substitution is possible.

Throughout the entirety of the description and claims of this specification, where subject matter is described herein using the term “comprise” (or “comprises” or “comprising”), the same subject matter instead described using the term “consist of” (or “consists of” or “consisting of”) or “consist essentially of” (or “consists essentially of” or “consisting essentially of”) is also contemplated.

Throughout the description and claims of this specification, the singular encompasses the plural unless the context otherwise requires. In particular, where the indefinite article is used, the specification is to be understood as contemplating plurality as well as singularity, unless the context requires otherwise.

Features described in conjunction with a particular aspect, embodiment or example of the invention are to be understood to be applicable to any other aspect, embodiment or example described herein unless incompatible therewith. All of the features disclosed in this specification (including any accompanying claims, abstract and drawings), and/or all of the steps of any method or process so disclosed, may be combined in any combination, except combinations where at least some of such features and/or steps are mutually exclusive. The invention is not restricted to the details of any of the specific embodiments recited herein. The invention extends to any novel one, or any novel combination, of the features disclosed in this specification (including any accompanying claims, abstract and drawings), or to any novel one, or any novel combination, of the steps of any method or process so disclosed.

As described hereinbefore, a first aspect of the invention provides a compound comprising a unit of formula (I):

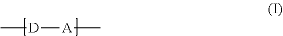

wherein
D is a collinear, π-electron rich group of formula (II)

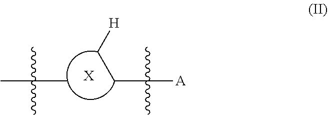

wherein:
X is a polycyclic, π-conjugated, ring system; and
A is a collinear, π-electron deficient group of formula (III):

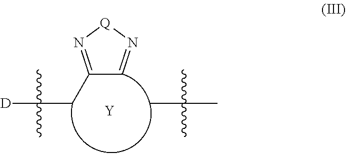

wherein:
Q is selenium or tellurium; and
Y is a monocyclic or polycyclic, π-conjugated, ring system.

Through rigorous investigations, the inventors have devised new conjugated compounds (e.g. polymers) having improved charge mobility. The compounds comprise collinear π-electron rich and π-electron deficient adjacent units having increased planarity as a consequence of non-covalent, intramolecular short-contacts. In particular, the inventors have recognised that the use of a large chalcogen atom in π-electron deficient units of formula (III) enhances the interaction between the nitrogen atom adjacent to the chalcogen atom and the peripheral hydrogen atom of the π-electron rich unit of formula (II). This enhanced N-H interaction planarizes the adjacent units, thereby rigidifying the compound as a whole, leading to improved charge mobility. This interaction is depicted below for illustrative purposes.

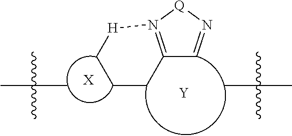

It will be understood that the term “collinear” used herein in relation to groups D and A refers to the bonds on either side of the group being parallel to one another. Thus, a collinear group D indicates that the bonds on either side of group D (at least one of which being bonded to group A) are parallel to one another. Similarly, a collinear group A indicates that the bonds on either side of group A (at least one of which being bonded to group D) are parallel to one another.

It will be understood that the term “π-electron rich” used herein refers to a π-conjugated, ring system in which the electron density per aromatic nucleus is greater than in benzene. Similarly, it will be understood that the term “π-electron deficient” used herein refers to a π-conjugated, ring system in which the electron density per aromatic nucleus is lower than in benzene.

X and Y are π-conjugated, ring systems and are directly linked to one another, as depicted in formula (I), (II) and (III). Accordingly, it will be understood that X is in conjugation with Y.

Y may be a monocyclic, π-conjugated ring system, such as a 6-membered aromatic or heteroaromatic ring. Alternatively, Y may be a polycyclic, π-conjugated ring system, such as a ring system comprising 5-or 6-membered aromatic or heteroaromatic fused rings (e.g. 2-5 fused rings). It will be understood that any ring in the ring system of Y may be substituted (e.g. with a group R^{X} as defined herein).

When Y is a polycyclic, π-conjugated ring system, one or more (but not all) of the rings may have a structure according to formula (IV):

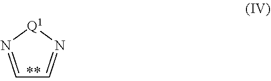

wherein:
Q¹ is oxygen, sulfur, selenium or tellurium; and
** denotes the bond shared with the one or more π-conjugated rings.

Y may be composed of one or more optionally-substituted 6-membered aromatic or heteroaromatic rings (e.g. benzene, pyridine or pyridazine), any one of which is optionally fused to a ring having a structure according to formula (IV). Suitably, Y is composed of one or more optionally-substituted benzene rings, any one of which is optionally fused to a ring having a structure according to formula (IV).

In embodiments, A is a collinear, π-electron deficient group of formula (IIIa), (IIIb), (IIIc) or (IIId):

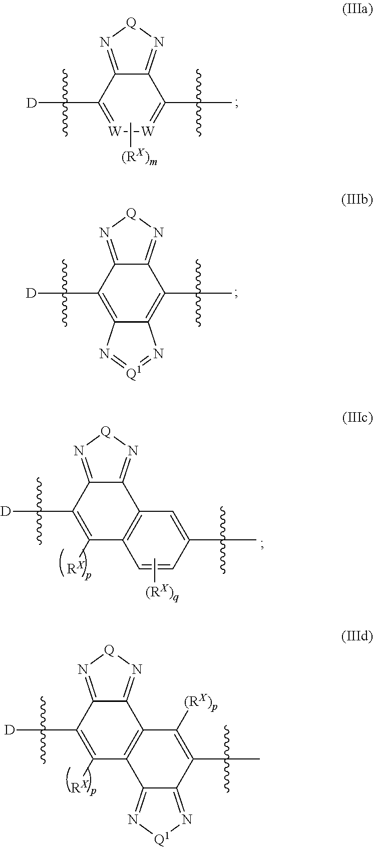

wherein:
Q is selenium or tellurium;
each W is nitrogen or carbon;
each R^{X} is independently selected from the group consisting of nitro, cyano, halo, alkyl, haloalkyl, alkoxy and haloalkoxy;
Q¹ is oxygen, sulfur, selenium or tellurium
when W is nitrogen, m is 0, and when W is carbon, m is 0, 1 or 2;
each p is independently 0 or 1; and
q is 0, 1, 2 or 3.

Q is most suitably selenium.

Q¹ may be sulfur, selenium or tellurium. Suitably, Q¹ is selenium or tellurium.

Q and Q¹ are suitably identical.

Each R^{X} may be independently selected from the group consisting of halo and alkoxy.

Alternatively, each R^{X} is independently selected from the group consisting of nitro, cyano, fluoro, (1-3C) alkoxy (e.g. methoxy), (1-3C) fluoroalkyl (e.g. trifluoromethyl) and (1-3C) alkyl (e.g. methyl). Most suitably, each R^{X} is independently fluoro or methoxy. Suitably, all R^{X} are identical.

m may be 0, 1 or 2, with both of p and q being 0.

In other embodiments, A is a collinear, π-electron deficient group of formula (IIIa), (IIIb), (IIIc-i) or (IIId-i):

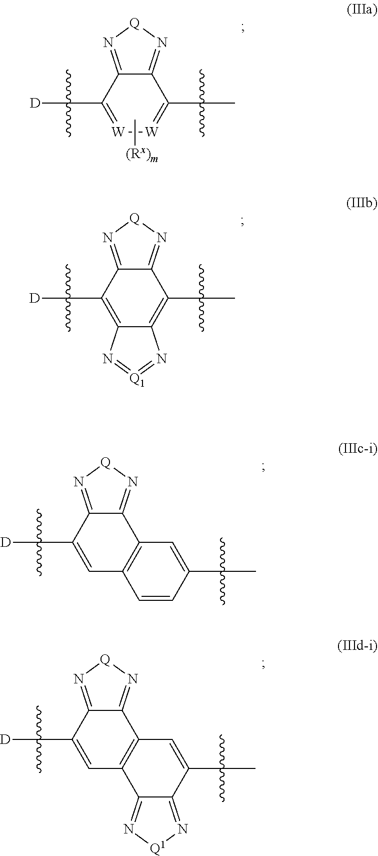

wherein Q, Q¹, W, R^{X} and m have any of those definitions recited hereinbefore.

Suitably, A is a collinear, π-electron deficient group of formula (IIIa). More suitably, A is a collinear, π-electron deficient group of formula (IIIa-i), (IIIa-ii), (IIIa-iii), (IIIa-iv), (IIIa-v), (IIIa-vi) or (IIIa-vii):

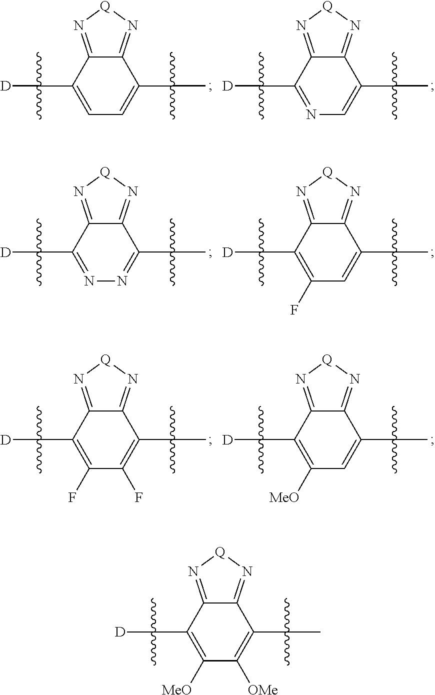

wherein Q has any of those definitions recited hereinbefore.

Particularly suitably, A is

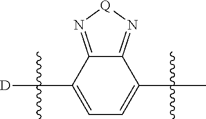

wherein Q has any of those definitions recited hereinbefore.

Most suitably, A is

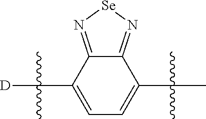

X may comprise a plurality of fused, 5-and/or 6-membered, π-conjugated rings. Suitably, X comprises 2-15 fused, π-conjugated rings. It will be understood that any ring in the ring system of X may be substituted (e.g. with a group R^{Y} as defined herein). The skilled person will be familiar with π-electron rich groups of formula D and the positions at which they can be substituted.

In embodiments, D is a collinear, π-electron rich group of formula (IIa):

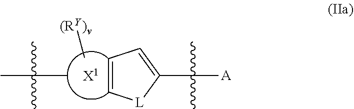

wherein:
X¹ is a monocyclic or polycyclic π-conjugated ring system;
Each R^{Y} is independently selected from the group consisting of hydroxy, cyano, halo, alkyl, alkenyl and alkynyl, optionally wherein one or more carbon atom in the alkyl, alkenyl and alkynyl group is replaced by a heteroatom (e.g. a polyethylene glycol group);
v is 0, 1, 2, 3, 4, 5 or 6; and
L is sulfur, oxygen, nitrogen or selenium.

X¹ may be a monocyclic π-conjugated ring system (e.g. a 5-or 6-membered ring, such as thiophene). Alternatively, X¹ may be a polycyclic, π-conjugated ring system having 2-14 rings (e.g. 5-or 6-membered rings). Suitably, when X¹ is a polycyclic, π-conjugated ring system, it comprises 3-14 rings (e.g. 5-or 6-membered rings).

In embodiments, D is a collinear, π-electron rich group of formula (Ilb):

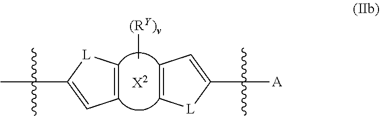

wherein:
X² is absent, or is a monocyclic or polycyclic π-conjugated ring system;
each R^{Y} is independently selected from the group consisting of hydroxy, cyano, halo, alkyl, alkenyl and alkynyl, optionally wherein one or more carbon atom in the alkyl, alkenyl and alkynyl group is replaced by a heteroatom (e.g. a polyethylene glycol group);
v is 0, 1, 2, 3, 4, 5 or 6; and
each L is independently sulfur, oxygen, nitrogen or selenium.

X² may be absent (e.g. in the case of thienothiophene). Alternatively, X² be a monocyclic π-conjugated ring system (e.g. a 5-or 6-membered ring, such as benzene). Alternatively still, X² may be a polycyclic, π-conjugated ring system having 2-13 rings (e.g. 5-or 6-membered rings).

Suitably, all groups L are identical. Most suitably, L is sulfur.

v may be 0, 1, 2, 3 or 4. Often, v is 4.

In particular embodiments, D is a collinear, π-electron rich group selected from the group consisting of thioenothiophene (TT), thieno[2′,3′:4,5]thieno[3,2-b]thieno[2,3-d]thiophene (TTTT), indacenodithiophene (IDT), indacenodithieno[3,2-b]dithiophene (IDTT), indacenodithieno[3,2-b:2′,3′-d]thiophene (IDTTT), indacenodithieno[3,2-b]dibenzo[1,2-b:4,5-b′]thiophene (TBIDT), indacenodithienodinaphtho [2,3-b:6,7-b′]thiophene (TNIDT), indacenodithienodibenzo[b]thieno[2,3-d]thiophene (TTBIDT), indacenodithienodithieno[2′,3′:4,5]thieno[3,2-b]thieno[2,3-d]thiophene (IDTTTT), indacenodithienodithieno[2,3-d]benzo[1,2-b:4,5-b′]thiophene (TBTIDT), dithieno[3,2-b]indenofluorene (TIF); dithieno[2,3-d]thienoindenofluorene (TTIF), dithienobenzo[1,2-b:4,5-b′]indenofluorene (TBIF), dithienonaphtho[1,2-b:4,5-b′]indenofluorene (TBBIF), dithieno[2,3-d]thienodibenzo[1,2-b:4,5-b′]indenofluorene (TTBIF), dithienodithieno[2′,3′:4,5]thieno[3,2-b]thieno[2,3-d]thienoindenofluorene (TTTIF) and dithieno[2,3-d]benzo[1,2-b:4,5-b′]thienoindenofluorene (TBTTIF), any one of which is optionally substituted with one or more R^{Y} as defined herein. The skilled person will be familiar with the aforementioned π-electron rich groups and the positions at which they can be substituted.

R^{Y} may be selected from the group consisting of hydroxy, cyano, halo, (1-30C) alkyl, (2-30C) alkenyl and (2-30C) alkynyl, optionally wherein one or more carbon atom in the alkyl, alkenyl and alkynyl group is replaced by a heteroatom (e.g. a polyethylene glycol group, such as one having up to 10 repeating units). Most suitably, R^{Y} is alkyl (e.g. (8-20C) alkyl). Suitably, all R^{Y} groups are identical.

Suitably, D is a collinear, π-electron rich group selected from the group consisting of indacenodithiophene (IDT), dithieno[3,2-b]indenofluorene (TIF), indacenodithieno[3,2-b]dibenzo[1,2-b:4,5-b′]thiophene (TBIDT) and dithieno[2,3-d]thienoindenofluorene (TTIF), any one of which is optionally substituted with one or more R^{Y}.

Particularly suitably, D is indacenodithiophene (IDT) optionally substituted with one or more R^{Y} (e.g. (8-20C) alkyl).

Most suitably, D is:

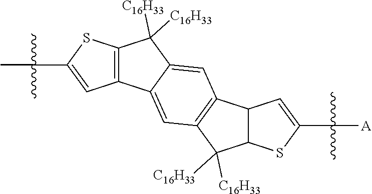

In particular embodiments, A is:

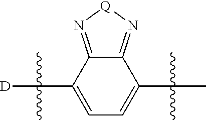

and D is indacenodithiophene (IDT) optionally substituted with one or more R^{Y}. Suitably R^{Y} is alkyl (e.g. (8-20C) alkyl). More suitably, Q is selenium.

Most suitably, A is:

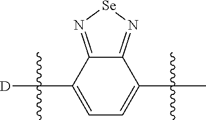

### and D is:

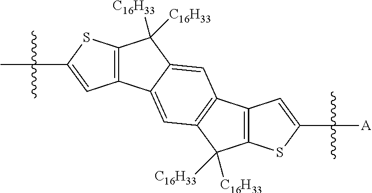

Suitably, the unit of formula (I) is itself collinear. It will be understood that when the unit of formula (I) is collinear, the bonds on either side of the unit are parallel to one another.

The compound may comprise (of consist of) a plurality of units of formula (I). The units are suitably identical to one another.

In particularly suitable embodiments, the compound is a polymer or oligomer comprising (or consisting of) a plurality of units of formula (I). Suitably, the units are identical to one another. Most suitably, the compound is a polymer comprising (or consisting of) a plurality of identical repeating units of formula (I) (e.g. a donor-acceptor copolymer). The compound (e.g. polymer) is suitably semiconductive.

When the compound is a polymer, it may have a structure according to formula (Ia):

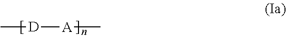

where n is greater than 1. Suitably, n is greater than 10. More suitably, n is greater than 100. n may be less than 100,000 (e.g. less than 10,000 or less than 5000).

Thus, in a further aspect, the invention provides a polymer having a repeating unit of formula (Ib):

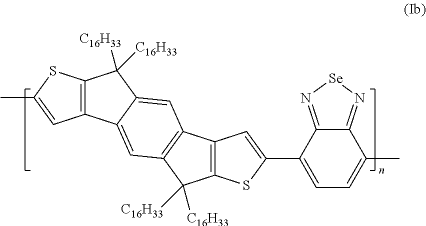

where n is as defined herein.

As described hereinbefore, a second aspect of the invention provides an electronic device or component comprising a compound (or polymer) as defined herein.

In particular embodiments, the electronic device or component is a transistor (e.g. an organic thin film transistor).

As described hereinbefore, a third aspect of the invention provides a use of a polymer or oligomer defined herein as a semiconducting material (e.g. in a transistor, such as an organic thin film transistor).

The following numbered statements 1 to 50 are not claims, but instead describe particular aspects and embodiments of the invention:

1. A compound comprising a unit of formula (I):

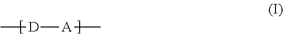

wherein
D is a collinear, π-electron rich group of formula (II)

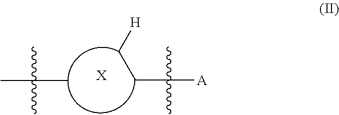

wherein:
X is a polycyclic, π-conjugated, ring system; and
A is a collinear, π-electron deficient group of formula (III):

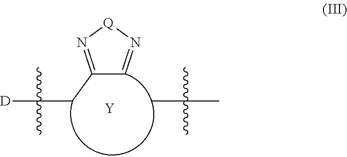

wherein:
Q is selenium or tellurium; and
Y is a monocyclic or polycyclic, π-conjugated, ring system:
2. The compound of statement 1, wherein Y is:
a monocyclic, π-conjugated ring system, being a 6-membered aromatic or heteroaromatic ring; or
a polycyclic, π-conjugated ring system, being a ring system comprising 5-or 6-membered aromatic or heteroaromatic fused rings (e.g. 2-5 fused rings).
3. The compound of statement 1 or 2, wherein when Y is a polycyclic, π-conjugated ring system, one or more (but not all) of the rings may have a structure according to formula (IV):

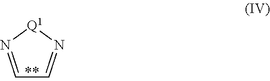

wherein:
Q¹ is oxygen, sulfur, selenium or tellurium; and
** denotes the bond shared with the one or more π-conjugated rings.
4. The compound of statement 3, wherein Y is composed of one or more optionally-substituted 6-membered aromatic or heteroaromatic rings (e.g. benzene, pyridine or pyridazine), any one of which is optionally fused to a ring having a structure according to formula (IV).
5 The compound of statement 3, wherein Y is composed of one or more optionally-substituted benzene rings, any one of which is optionally fused to a ring having a structure according to formula (IV).
6. The compound of statement 1, wherein A is a collinear, π-electron-accepting group of formula (IIIa), (IIIb), (IIIc) or (IIId):

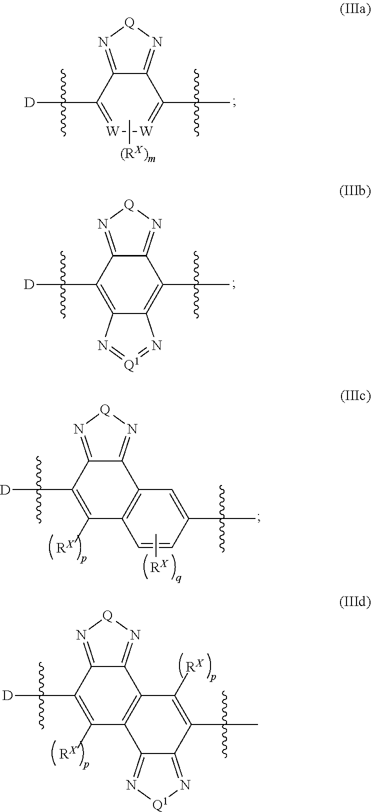

wherein:
Q is selenium or tellurium;
each W is nitrogen or carbon;
each R^{X} is independently selected from the group consisting of nitro, cyano, halo, alkyl, haloalkyl, alkoxy and haloalkoxy;
Q¹ is oxygen, sulfur, selenium or tellurium;
when W is nitrogen, m is 0, and when Wis carbon, m is 0, 1 or 2;
each p is independently 0 or 1; and
q is 0, 1, 2 or 3.
8. The compound of statement 7, wherein m is 0, 1 or 2, and p and q are 0.
9. The compound of statement 1, wherein A is a collinear, π-electron-accepting group of formula (IIIa), (IIIb), (IIIc-i) or (IIld-i):

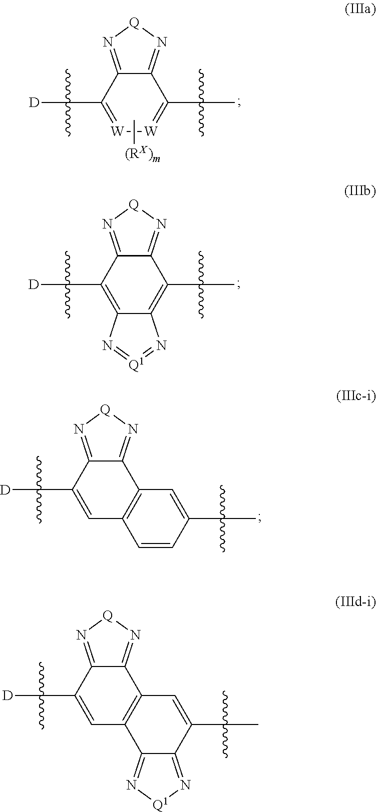

wherein:
Q is selenium or tellurium;
each W is nitrogen or carbon;
each R^{X} is independently selected from the group consisting of nitro, cyano, halo, alkyl, haloalkyl, alkoxy and haloalkoxy;
Q¹ is oxygen, sulfur, selenium or tellurium; and
when W is nitrogen, m is 0, and when Wis carbon, m is 0, 1 or 2.
10. The compound of statement 7, 8 or 9, wherein Q is selenium.
11. The compound of any one of statements 7 to 11, wherein Q1 is sulfur, selenium or tellurium.
12. The compound of any one of statements 7 to 11, wherein Q¹ is selenium or tellurium.
13. The compound of statement 12, wherein Q and Q¹ are identical.
14. The compound of any one of statements 7 to 13, wherein each R^{X} is independently selected from the group consisting of halo and alkoxy.
15. The compound of any one of statements 7 to 13, wherein each R^{X} is selected from the group consisting of nitro, cyano, fluoro, (1-3C) alkoxy (e.g. methoxy), (1-3C) fluoroalkyl (e.g. trifluoromethyl) and (1-3C) alkyl (e.g. methyl).
16. The compound of statements 15, wherein each R^{X} is selected from the group consisting of fluoro and methoxy.
17. The compound of any one of statements 7 to 16, wherein all R^{X} are identical.
18. The compound of any one of the preceding statements, wherein A is a collinear, π-electron deficient group of formula (IIIa-i), (IIIa-ii), (IIIa-iii), (IIIa-iv), (IIIa-v), (IIIa-vi) or (IIIa-vii):

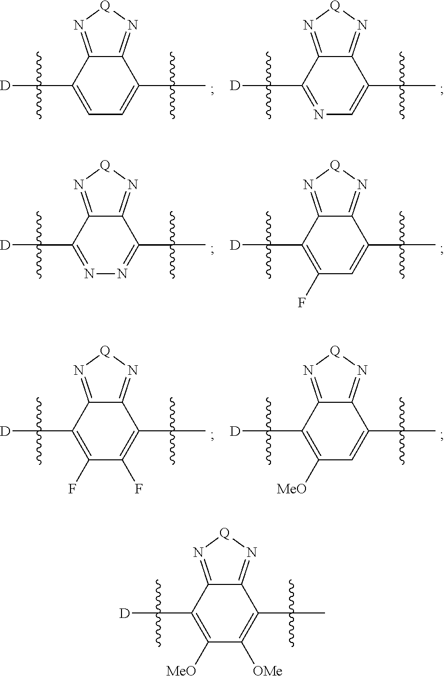

wherein Q has any of those definitions recited in any preceding statement.
19. The compound of any one of the preceding statements, wherein A is

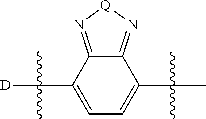

wherein Q has any of those definitions recited in any preceding statement.
20. The compound of statement 1, wherein A is

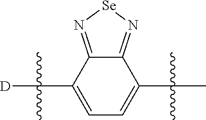

21. The compound of any one of the preceding statements, wherein X comprises a plurality of fused, 5-and/or 6-membered, π-conjugated rings.
22. The compound of statement 21, wherein X comprises 2-15 fused, π-conjugated rings.
23. The compound of any one of the preceding statements, wherein D is a collinear, π-electron rich group of formula (IIa):

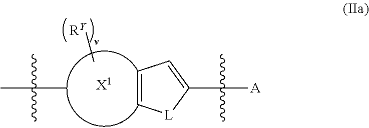

wherein:
X¹ is a monocyclic or polycyclic T-conjugated ring system;
Each R^{Y} is independently selected from the group consisting of hydroxy, cyano, halo, alkyl, alkenyl and alkynyl, optionally wherein one or more carbon atom in the alkyl, alkenyl and alkynyl group is replaced by a heteroatom (e.g. a polyethylene glycol group);
v is 0, 1, 2, 3, 4, 5 or 6; and
L is sulfur, oxygen, nitrogen or selenium.
24. The compound of statement 23, wherein X¹ is:
a monocyclic π-conjugated ring system (e.g. a 5-or 6-membered ring, such as thiophene); or
a polycyclic, π-conjugated ring system having 2-14 rings (e.g. 5-or 6-membered rings).

25. The compound of any one of the preceding statements, wherein D is a collinear, π-electron rich group of formula (IIb):

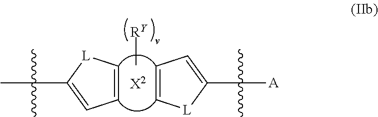

wherein:
X² is absent, or is a monocyclic or polycyclic π-conjugated ring system;
each R^{Y} is independently selected from the group consisting of hydroxy, cyano, halo, alkyl, alkenyl and alkynyl, optionally wherein one or more carbon atom in the alkyl, alkenyl and alkynyl group is replaced by a heteroatom (e.g. a polyethylene glycol group);
v is 0, 1, 2, 3, 4, 5 or 6; and
each L is independently sulfur, oxygen, nitrogen or selenium.
26. The compound of statement 26, wherein X² is:
absent (e.g. in the case of thienothiophene);
a monocyclic π-conjugated ring system (e.g. a 5-or 6-membered ring, such as benzene); or
a polycyclic, π-conjugated ring system having 2-13 rings (e.g. 5-or 6-membered rings).
27. The compound of any one of statements 23 to 26, wherein all L groups are identical.
28. The compound of any one of statements 23 to 27, wherein L is sulfur.
29. The compound of any one of statements 23 to 28, wherein each R^{Y} is independently selected from the group consisting of alkyl or a polyethylene glycol group (e.g. having up to 10 repeating units).
30. The compound of any one of statements 23 to 28, wherein each R^{Y} independently selected from the group consisting of alkyl (e.g. (8-20 C) alkyl).
31. The compound of any one of statements 23 to 28, wherein all R^{Y} are identical.
32. The compound of any one of statements 23 to 31, wherein Vis 0, 1, 2, 3 or 4.
33. The compound of any one of the preceding statements, wherein D is a collinear, π-electron rich group selected from the group consisting of thioenothiophene (TT), thieno[2′,3′:4,5]thieno[3,2-b]thieno[2,3-d]thiophene (TTTT), indacenodithiophene (IDT), indacenodithieno[3,2-b]dithiophene (IDTT), indacenodithieno[3,2-b:2′,3′-d]thiophene (IDTTT), indacenodithieno[3,2-b]dibenzo[1,2-b:4,5-b′]thiophene (TBIDT), indacenodithienodinaphtho [2,3-b:6,7-b′]thiophene (TNIDT), indacenodithienodibenzo[b]thieno[2,3-d]thiophene (TTBIDT), indacenodithienodithieno[2′,3′:4,5]thieno[3,2-b]thieno[2,3-d]thiophene (IDTTTT), indacenodithienodithieno[2,3-d]benzo[1,2-b:4,5-b′]thiophene (TBTIDT), dithieno[3,2-b]indenofluorene (TIF); dithieno[2,3-d]thienoindenofluorene (TTIF), dithienobenzo[1,2-b:4,5-b′]indenofluorene (TBIF), dithienonaphtho [1,2-b:4,5-b′]indenofluorene (TBBIF), dithieno[2,3-d]thienodibenzo[1,2-b:4,5-b′]indenofluorene (TTBIF), dithienodithieno[2′,3′:4,5]thieno[3,2-b]thieno[2,3-d]thienoindenofluorene (TTTIF) and dithieno[2,3-d]benzo[1,2-b:4,5-b′]thienoindenofluorene (TBTTIF), any one of which is optionally substituted with one or more (e.g. up to 4) R^{Y}.
34. The compound of any one of the preceding statements, wherein D is a collinear, π-electron rich group selected from the group consisting of indacenodithiophene (IDT), dithieno[3,2-b]indenofluorene (TIF), indacenodithieno[3,2-b]dibenzo[1,2-b:4,5-b′]thiophene (TBIDT) and dithieno[2,3-d]thienoindenofluorene (TTIF), any one of which is optionally substituted with one or more R^{Y}.
35. The compound of any one of the preceding statements, wherein D is indacenodithiophene (IDT) optionally substituted with one or more R^{Y} (e.g. where R^{Y} is alkyl, such as (8-20C) alkyl).
36. The compound of any one of the preceding statements, wherein D is:

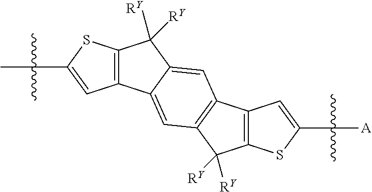

wherein each R^{Y} is independently as defined in any preceding statement.
37. The compound of statement 36, wherein R^{Y} is —C₁₆H₃₃.
38. The compound of any one of the preceding statements, wherein A is:

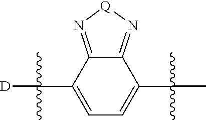

and D is indacenodithiophene (IDT) optionally substituted with one or more R^{Y} as defined any preceding statement.
39. The compound of any one of the preceding statements, wherein A is:

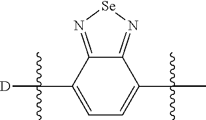

and D is:

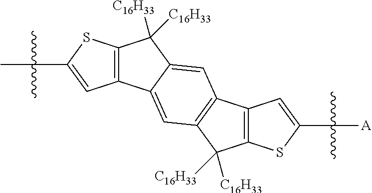

40. The compound of any one of the preceding statement, wherein the unit of formula (I) is itself collinear.
41. The compound of any one of the preceding statements, wherein the compound comprises a plurality of units of formula (I).
42. The compound of statement 41, wherein the plurality of units of formula (I) are identical.
43. The compound of any one of the preceding statements, wherein the compound is a polymer or an oligomer.
44. The compound of statement 43, wherein the polymer or oligomer is an alternating donor-acceptor polymer or oligomer.
45. The compound of any one of the preceding statements, wherein the compound is a polymer having a structure according to formula (Ia):

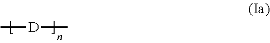

where n is greater than 1 (greater than 10).
46. The compound of any one of the preceding statements, wherein the compound is semiconductive.
47. A polymer having a repeating unit of formula (Ib):

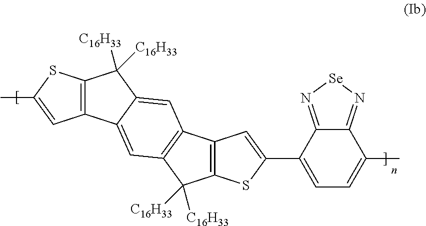

where n is greater than 1 (e.g. greater than 10).
48. An electronic device or component comprising a compound or polymer of any one of the preceding statements.
49. The electronic device of component of statement 48, wherein the electronic device or component is a transistor (e.g. an organic thin film transistor).
50. Use of a compound (e.g. a polymer or oligomer) as defined in any preceding statement as a semiconducting material.

### EXAMPLES

One or more examples of the invention will now be described, for the purpose of illustration only, with reference to the accompanying figures:

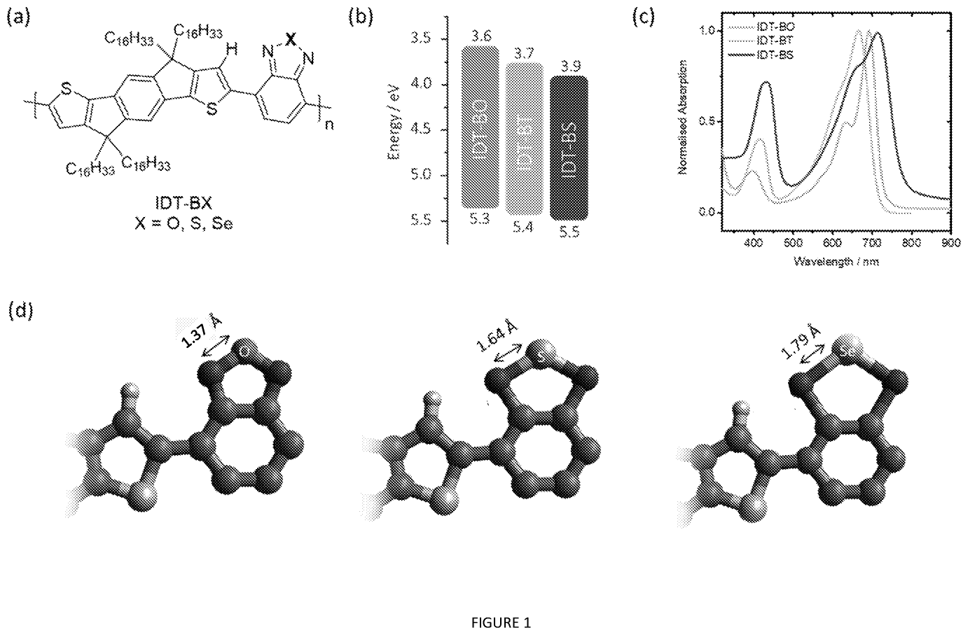

FIG. 1. (a) Chemical structure of IDT-BO, IDT-BT and IDT-BS. (b) Energy levels of the polymers IDT-BO, IDT-BT and IDT-BS, derived from PESA and the optical band-gap. (c) Normalised UV-vis absorption spectra for thin films of the polymers. (d) IIIustration of the effect of chalcogen atom variation on the N—X bond length and N—H short contact in IDT-BT analogues. Where X=oxygen (O), sulfur(S) or selenium (Se).

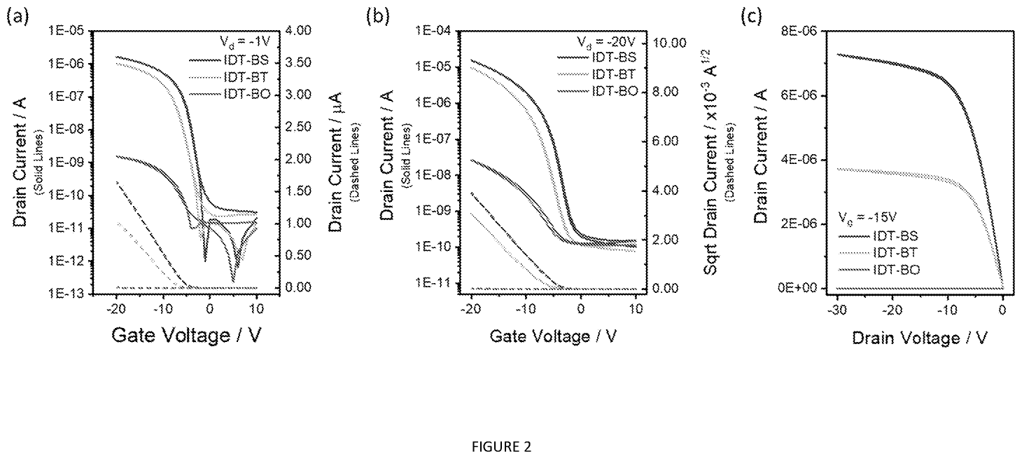

FIG. 2. For OTFTs based on the polymers IDT-BS, IDT-BT and IDT-BO the (a) linear transfer characteristics, where a drain voltage (V_{d}) of −1 V is applied, (b) saturation transfer characteristics, where a V_{d} of −20 V is applied and (c) output characteristics, where a gate voltage (Vg) of −15 V is applied.

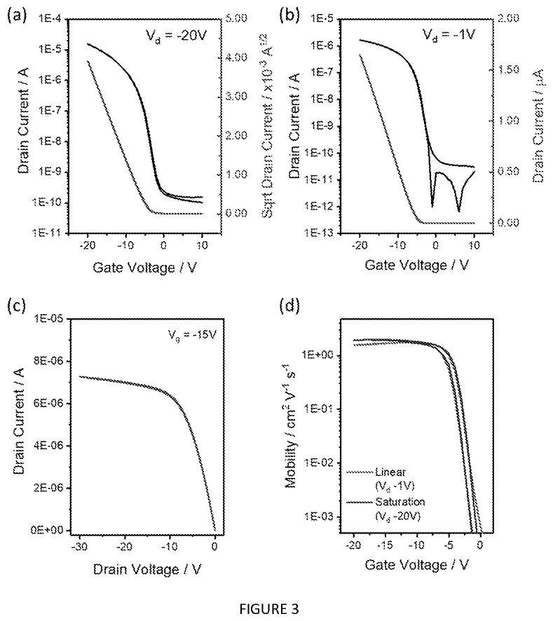

FIG. 3. For OTFTs based on IDT-BS. (a) Transfer plot for OTFTs operating in the saturation regime, where drain voltage (V_{d}) is −20V. (b) Linear transfer plot for OTFTs operating in the saturation regime, where V_{d} is −1V. (c) Output plot, where gate voltage (V_{g}) is −15V. (d) Calculated mobility as a function of gate voltage for OTFTs operating in the linear saturation regimes.

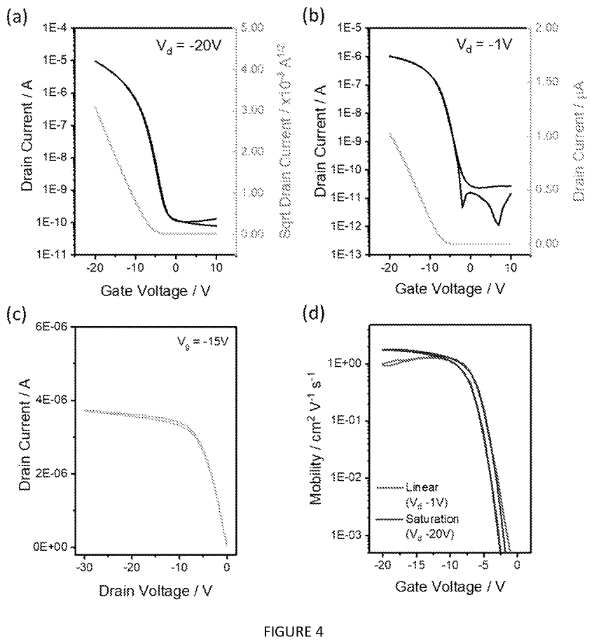

FIG. 4. For OTFTs based on IDT-BT. (a) Transfer plot for OTFTs operating in the saturation regime, where drain voltage (V_{d}) is −20V. (b) Linear transfer plot for OTFTs operating in the saturation regime, where V_{d} is −1V. (c) Output plot, where gate voltage (V_{g}) is −15V. (d) Calculated mobility as a function of gate voltage for OTFTs operating in the linear saturation regimes.

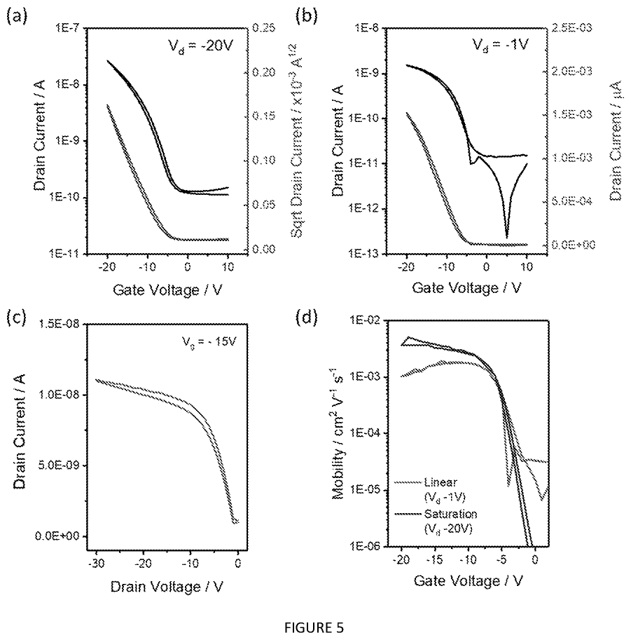

FIG. 5. For OTFTs based on IDT-BO. (a) Transfer plot for OTFTs operating in the saturation regime, where drain voltage (V_{d}) is −20V. (b) Linear transfer plot for OTFTs operating in the saturation regime, where V_{d} is −1V. (c) Output plot, where gate voltage (V_{g}) is −15V. (d) Calculated mobility as a function of gate voltage for OTFTs operating in the linear saturation regimes.

### Materials and Methods

Organic thin film transistor (OTFT) Characterisation: For the transfer curves, the gate voltage was varied from +10 to −20 V (with an increment of 1 V) while applying a drain voltage of −1 and −20 V for the linear and saturation regime, respectively. The output curves were measured by applying a gate voltage of −15 V and performing a drain voltage swipe from 0 to −30 V (with an increment of 1 V). All the thin film transistors (TFTs) have a W/L ratio of 20.

Photoelectron Spectroscopy in Air (PESA): Riken Keiki AC-2 PESA spectrometer with a power setting of 5 nW and a power number of 0.2. Samples for PESA were prepared on glass substrates by spin-coating.

### Synthesis of Polymers

Taking indaceno[1,2-b:5,6-b′]dithiophene-co-2, 1,3-benzoselenadiazole (IDT-BS) as an example, IDT-BS and the comparators indaceno[1,2-b:5,6-b′]dithiophene-co-2,1,3-benzoxadiazole (IDT-BO) and indaceno[1,2-b:5,6-b′]dithiophene-co-2, 1,3-benzothiadiazole (IDT-BT) were prepared in accordance with the approach outlined in Scheme 1 below and described thereafter.

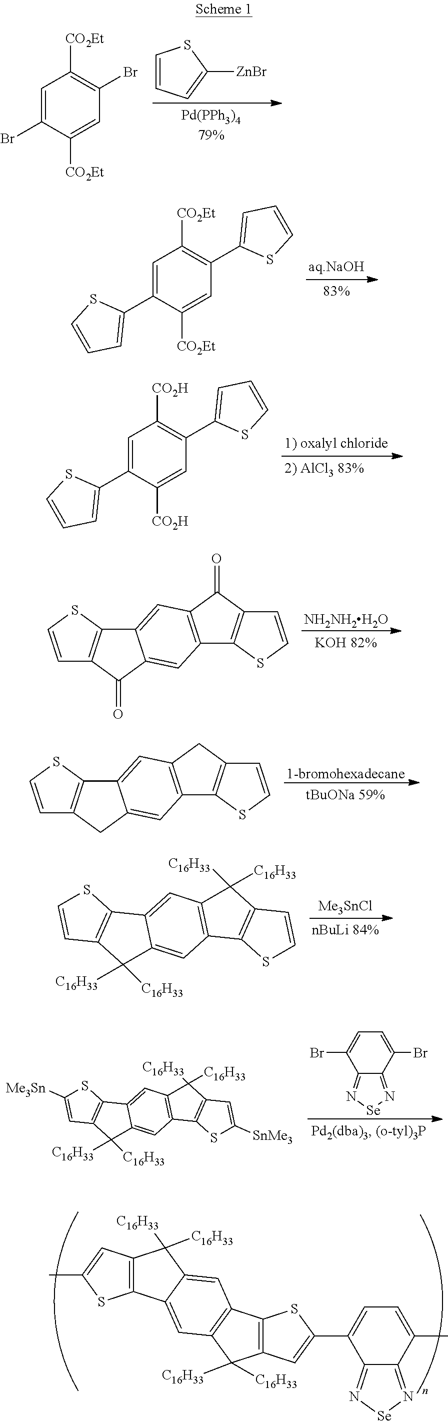

2,5-dithien-2-ylterephthalic acid diethyl ester A mixture of diethyl 2,5-dibromoterephthalate (4.27 g, 11.24 mmol), 2-thienylzinc bromide (0.50 M in THF, 50 ml, 25.0mmol) and Pd (PPh3) 4 (0.39 g, 0.34 mmol) was heated at reflux for 3 h. After cooled to room temperature, the reaction mixture was poured into sat. NH4Cl solution. The product was extracted with ethyl acetate (3×100 ml). The extracts were combined and washed with water and brine then dried over sodium sulphate. After filtration, the solvent was removed under reduced pressure. The residue was purified by column chromatography on silica, eluting with hexanes/ethyl acetate (from 10:0 to 9:1), to give 2,5-dithien-2-ylterephthalic acid diethyl ester as pale yellow solid (3.43 g, 79%). 1H NMR (400 MHZ, CDCl3): δ(ppm) 7.83 (s, 2H, Ar-H), 7.41 (dd, J=4.8 and 1.4 Hz, 2H, Ar-H), 7.10-7.13 (m, 4H, Ar-H), 4.24 (q, J=7.2 Hz, 4H, CH2), 1.18 (t, J=7.2 Hz, 6H, CH3).

2,5-dithien-2-ylterephthalic acid 2,5-Dithien-2-ylterephthalic acid diethyl ester (3.20 g, 8.28 mmol) was dissolved in ethanol (200 ml), followed by the addition of a solution of sodium hydroxide (4.50 g NaOH in 30 ml water). This mixture was heated at reflux for 15 h, then evaporated under reduced pressure. Water then concentrated hydrochloric acid was added to the residue. The precipitate formed was collected by filtration and washed with water then dried in vacuo to afford product as off-white solid (2.27 g, 83%). 1H NMR (400 MHZ, DMSO-d6): δ(ppm) 13.48 (s, 2H, COOH), 7.73 (s, 2H, Ar-H), 7.72 (dd, J=5.1 and 1.1 Hz, 2H, Ar-H), 7.30 (dd, J=3.6 and 1.1 Hz, 2H, Ar-H), 7.18 (m, 2H, Ar-H); 13C NMR (100 MHZ, DMSO-d6): δ(ppm) 168.8 (C═O), 139.7 (q), 134.6 (q), 131.5 (q), 130.3 (CH), 127.9 (CH), 127.6 (CH), 127.2 (CH).

4,9-dihydro-s-indaceno[1,2-b:5,6-b′]-dithiophene-4,9-dione 2,5-Dithien-2-ylterephthalic acid (2.13 g, 6.45 mmol) was suspended in anhydrous DCM (100 ml), followed by the addition of oxalyl chloride (3.28 g, 25.83 mmol). To this mixture anhydrous DMF (1 ml) was added dropwise at room temperature. The resultant mixture was stirred overnight. The solvent was removed under reduced pressure to afford crude acid dichloride as a yellow solid. This solid was dissolved in anhydrous DCM (80 ml) then added to a suspension of anhydrous AlCl3 (4 g) in DCM (120 ml) at 0° C. The resultant mixture was allowed to warm to room temperature and stirred overnight, then poured into ice-cold HCl solution. The precipitate was collected by filtration and washed with 2M HCl solution, water and acetone, then dried in vacuo to afford a deep blue soild (1.46 g, 77%). MS (m/e): 294 (M+, 100%), 281, 266, 207, 193; IR: v (cm-1) 1705 (C═O).

4,9-dihydro-s-indaceno[1,2-b:5,6-b′]-dithiophene A mixture of 4,9-dihydro-s-indaceno-[1,2-b:5,6-b′]-dithiophene-4,9-dione (1.33g, 4.52mmol), hydrazine monohydrate (4.52 g, 90.40 mmol) and KOH (5.07 g, 90.54 mmol) in diethylene glycol (50 ml) was heated at 180° C. for 24 h, then poured into ice containing hydrochloric acid. The precipitate was collected by filtration and washed with water and acetone, and dried in vacuo to give 4,9-dihydro-s-indaceno[1,2-b:5,6-b′]-dithiophene as pale yellow solid (0.98 g, 82%). 1H NMR (400 MHZ, DMSO-d6): δ(ppm) 7.73 (s, 2H, Ar-H), 7.56 (d, J=4.8Hz, 2H, Ar-H), 7.22 (d, J=4.8Hz, 2H, Ar-H), 3.79 (s, 4H, CH2).

4,9-dihydro-4,4,9,9-tetrahexadecyl-s-indaceno[1,2-b:5,6-b′]-dithiophene To a suspension of 4,9-dihydro-s-indaceno[1,2-b:5,6-b′]-dithiophene (0.92 g, 3.46 mmol) in anhydrous DMSO (20 ml) was added sodium tert-butoxide (1.99 g, 20.73 mmol) in parts. The reaction mixture was heated at 80° C. for 1 h, followed by the addition of 1-bromohexadecane (6.33 g, 20.75 mmol) dropwise. After complete addition, the resultant mixture was heated at 85° C. for 5 h, then poured into ice-water. The precipitate was collected by filtration and washed with water and methanol to give a black solid. This was purified by column chromatography on silica, eluting with hexanes, to give a off-white solid (2.38 g, 59%). 1H NMR (400 MHZ, CDCl3): δ(ppm) 7.29 (s, 2H, Ar-H), 7.27 (d, J=4.8 Hz, 2H, Ar-H), 6.98 (d, J=4.8 Hz, 2H, Ar-H), 1.94-2.04 (m, 4H, CH2), 1.81-1.92 (m, 4H, CH2) 1.02-1.46 (m, 104H, CH2), 0.75-0.98 (m, 20H, CH2 and CH3); (13C NMR (100 MHz, CDCl3): δ(ppm) 155.2, 153.2, 141.8, 135.7, 126.2, 121.7, 113.2, 53.8, 39.1,32.1, 30.1, 29.8, 29.7, 29.4, 24.3, 22.8, 14.2.

2,7-Dibromo-4,9-dihydro-4,4,9,9-tetrahexadecyl-s-indaceno[1,2-b:5,6-b′]-dithiophene To a solution of 4,9-dihydro-4,4,9,9-tetrahexadecyl-s-indaceno[1,2-b:5,6-b′]-dithiophene (2.17 g, 1.86 mmol) in THF/DMF (2:1, 100ml) was added N-bromosuccinimide (0.73 g, 4.10 mmol). This mixture was stirred for 3 h in the absence of light at room temperature, then pour into water. The precipitate was collected and washed with water then recystallized with acetone, to give product as pale yellow solid (2.11 g, 86%). 1H NMR (400 MHZ, CDCl3): δ(ppm) 7.19 (s, 2H, Ar-H), 6.98(s, 2H, Ar-H), 1.89-1.99 (m, 4H, CH2), 1.78-1.88 (m, 4H, CH2) 1.00-1.58 (m, 104H, CH2), 0.68 -0.96 (m, 20H, CH2 and CH3); (13C NMR (100 MHZ, CDCl3): δ(ppm) 154.2, 152.2, 141.9, 135.6, 124.9, 113.1, 112.5, 54.8, 39.1, 32.1, 29.9, 29.8, 29.7, 29.5, 29.4, 24.2, 22.8, 14.2.

(4,4,9,9-tetrahexadecyl-4,9-dihydro-s-indaceno[1,2-b:5,6-b′]dithiophene-2,7-diyl)bis(trimethylstannane) To a solution of 2,7-Dibromo-4,9-dihydro-4,4,9,9-tetrahexadecyl-s-indaceno[1,2-b:5,6-b′]-dithiophene dithiophene (1.16 g, 1 mmol) was added nButyl lithium (2.5M in THF, 3 mmol) under ice-bath, the mixture was stirred for 30 min, followed by the addition of Me3SnCI (1M in THF, 3 mmol). The mixture was stirred overnight and quenched by water. Basic Aluminum was used as the column layer to flash purify it. 1H NMR (500 MHZ, Methylene Chloride-d2) 0 7.33 (s, 2H), 7.06 (s, 2H), 2.01 (ddd, J=12.9, 10.9, 5.4 Hz, 4H), 1.89 (ddd, J=13.0, 10.9, 5.3 Hz, 4H), 1.42-1.04 (m, 104H), 0.99-0.69 (m, 20H), 0.43 (s, 18H); 13C NMR (126 MHZ, CD2Cl2) δ 157.63, 153.91, 148.00, 140.01, 135.77, 129.89, 113.81, 54.27, 54.06, 53.84, 53.62, 53.49, 53.41, 39.55, 32.35, 30.41, 30.13, 30.11, 30.08, 30.05, 29.98, 29.78, 29.76, 24.60, 23.11, 14.30, -8.02.

Synthesis of IDT-BS A 20 mL glass vial was charged with (4,4,9,9-tetrahexadecyl-4,9-dihydro-s-indaceno[1,2-b:5,6-b′]dithiophene-2,7-diyl) bis (trimethylstannane) (0.223 g, 0.15mmol), 4,7-dibromobenzo[c][1,2,5]selenadiazole (0.051 g, 0.15 mmol), Pd2 (dba) 3 (3.01 mg, 3.3×10-3 mmol), (o-tol) 3P (4.03 mg, 0.0132 mmol), chlorobenzene (5 ml). This mixture was degassed with argon for 30 min, then sealed and heated at 120 oC for 48 h. The polymer was precipitated from methanol, then collected by filtration and washed with water. The polymer was further purified by washing via Soxhlet Extraction with methanol (24 h), acetone (24 h), hexanes (24 h) then dissolved in chloroform and reprecipitated into methanol. The polymer was filtered and washed with methanol and acetone, then dried in vacuo to give product IDT-BS as a deep blue solid. Fractional GPC could be used to narrow down the PDI and increase the molecular weight. Comparators IDT-BO and IDT-BT were synthesized using an analogous procedure to that outlined in Scheme 1.

### OTFT Fabrication

The thin film transistor structure used in these tests was a top gate bottom contact structure. The gold source drain contacts were prepared by photolithography on a 14″ PEN substrate, cut into 1″ chips and mounted on 1″ glass using an adhesive. A self-assembled monolayer (SAM) was coated on the source drain contacts ahead of the OSC deposition. Each organic semiconductor was spin coated on top of the source drain contacts at 500 rpm/15 s+900 rpm/60 s, then baked at 70 C for 5 min and 90C for 2 min. An organic gate dielectric was deposited on top of the OSC. The dielectric thickness is about 600nm. A metal alloy was used for the gate.

### Results and Discussion

The general chemical structures of the three benzochalcagenadiazole containing polymers: indaceno[1,2-b:5,6-b′]dithiophene-co-2,1,3-benzoxadiazole (IDT-BO), indaceno[1,2-b:5,6-b′]dithiophene-co-2,1,3-benzothiadiazole (IDT-BT) and indaceno[1,2-b:5,6-b′]dithiophene-co-2,1,3-benzoselenadiazole (IDT-BS) are presented in FIG. 1(a).

First, to determine the effect of increasing the chalcogen atom size on the planarity of the three polymers, the N—X bond length was calculated using density functional theorem (DFT). In benzoxadiazole, benzothiadiazole and benzoselenadiazole, the N—X bond lengths were calculated to be 1.37, 1.64 and 1.79 Å respectively. The N—X bond is shown to lengthen as the size of the chalcogen atom (X) increases from oxygen to sulfur to selenium, as illustrated in FIG. 1(d). These bond lengths were found to be independent of the dihedral angle between the IDT and benzochalcogenadiazole units. This bond lengthening suggests that on changing the chalcogen atom the nitrogen is forced closer to the IDT unit in the polymers.

The chalcogen atoms also differ in electronegativity, with selenium being the least electronegative and oxygen the most. Due to the lower electronegativity of the selenium atom compared to oxygen and sulfur the N—X bond is polarised N^{δ-}—S^{δ+}. As the nitrogen is more negatively polarised, not only will it lie closer to the adjacent proton, but it will also interact more strongly with the adjacent proton.

As can be seen from the normalised thin-film UV-vis absorption spectra in FIG. 1(c), IDT-BS exhibited a red shifted and broader absorption relative to IDT-BT, from a peak absorption, attributed to the π-π* transition, at 666 nm for IDT-BT to 713 nm for IDT-BS. Such a red-shift can be attributed to the lower electronegativity of selenium, which results in electrons being more easily donated to the conjugated system than electrons from sulfur. IDT-BO also exhibited a red-shift in absorption relative to IDT-BT. It is not clear what caused this red-shift but previously polymers combining thiophene co-monomers with benzothiadiazole and benzoxadiazole exhibited very similar peak absorptions to each other. The normalised UV-vis absorption spectra of the three polymers are presented in FIG. 1(c).

The ionisation potentials (IP) of the three polymers (Table 1), which can roughly be approximated as the HOMO levels, were determined using photoemission spectroscopy in air (PESA). The electron affinity (EA) values (Table 1), equated here to LUMO levels, were estimated by combining the IPs and optical-band gaps. The increase in EA across the polymer series, from 3.6 eV for IDT-BO, to 3.7 eV for IDT-BT and 3.9 eV for IDT-BS, was expected based on the increasing size and decreasing electronegativity of the chalcogen atoms, resulting in loss of aromaticity which leads to LUMO stabilisation.^{[16,17,18]}

Across the polymer series the IP increases from 5.3 eV for IDT-BO to 5.4 eV for IDT-BT to 5.5 eV for IDT-BS. This is in contrast with previously reported benzochalcagenadiazole containing polymers where the selenium containing polymer delivers a lower IP, attributed to destabilisation of the HOMO by the larger less electronegative atom.^{[19]} In another example a larger IP was predicted for a benzoxadiazole containing D-A polymer compared with the benzothiadiazole containing polymer, however, experimentally a negligible difference in IP energy was observed. Of particular importance for the operation of p-type OTFTs is the IP of the polymers, as an offset between the IP of the polymer and workfunction of the electrodes will result in a barrier to hole extraction, manifesting as contact resistance. For both IDT-BO and IDT-BS the observed difference in IP, as compared to IDT-BT, is 0.1 eV, indicating that the effect of chalcogen atom substitution should not significantly affect contact resistance in OTFTs.

TABLE 1
Weight and number averaged molecular weights (Mₙ/M_{w}), polydispersity (PDI), peak
wavelength in as cast thin-films (λₘₐₓ), optical bandgap (E_{g}), ionisation potential calculated from PESA
(IP), electron affinity calculated from the IP and E_{g} (EA) for IDT-BO, IDT-BT and IDT-BS

| Polymer | M_{w}/Mₙ (kDa) | PDI | λₘₐₓ (nm) | E_{g} (eV) | IP (eV) | EA (eV) |
|---|---|---|---|---|---|---|
| IDT-BO | 67/91 | 1.36 | 682 | 1.7 | 5.3 | 3.6 |
| IDT-BT | 101/280 | 2.77 | 666 | 1.7 | 5.4 | 3.7 |
| IDT-BS | 77/112 | 1.45 | 713 | 1.6 | 5.5 | 3.9 |

The performance of the three polymers was compared in staggered, top-gate OTFTs with channel width to length ratios of 20. A representative transfer curve of OTFTs based on each polymer operating in both linear and saturation regime are displayed in FIG. 2 and individual plots are presented in the supplementary information FIGS. 3, 4 and 5. The figure of merit used to define how well a polymer performs in OTFTs is mobility. A high mobility is required to ensure fast switching of the OTFTs between their on and off state. However, significant concerns about the overestimation of mobility values due to the improper analysis of non-ideal OTFT transfer characteristics have been highlighted.^{[2.20]} As can be seen in FIGS. 2-5 the OTFTs fabricated in this study do not exhibit kinks in their transfer characteristics and the calculated mobility values are relatively gate voltage independent. The OTFTs fabricated with IDT-BS demonstrated the highest saturation mobility with an average of 1.9 cm² V⁻¹ s⁻¹ and values as high as 2 cm² V⁻¹ s⁻¹ for the best devices. In contrast, devices fabricated with IDT-BT showed an average mobility of 1.7 cm² V⁻¹ s⁻¹ with a maximum around 1.8 cm² V⁻¹ s⁻¹ . Finally, the IDT-BO exhibited the lowest mobility so far with an average of 3×10⁻³ cm² V⁻¹ s⁻¹ and a maximum of around 5.1×10⁻³ cm² V⁻¹ s⁻¹ . IDT-BS clearly exhibits improved OTFT performance compared to IDT-BT, while IDT-BO demonstrated the expected opposite trend with a dramatic performance drop being observed.

TABLE 2
OTFT data extracted from devices fabricated with IDT-BS, IDT-BT and IDT-BO as the OSC. For
each device the On-current (Ion) normalised for channel dimensions (Iₒₙ*L*W), threshold voltage (Vₜₕ)
and mobility are given for operation in the linear and saturation regime, where a drain voltage (V_{d}) of
−1 V and −20 V are applied respectively, are given. For each polymer, the data extracted from FIG.
3, 4 and 5 is displayed as well as the average of the 14 best devices.

| | | IDT-BS | | IDT-BT | | IDT-BO | |
|---|---|---|---|---|---|---|---|
| Regime | Parameter | Displayed | Average | Displayed | Average | Displayed | Average |
| Linear | Normalised | 8.3 × 10⁻⁸ | 7.4 × 10⁻⁸ | 5.1 × 10⁻⁸ | 4.7 × 10⁻⁸ | 7.7 × 10⁻¹¹ | 5.4 × 10⁻¹¹ |
| (Vd = −1 V) | Ion [A] | | | | | | |
| | (Ion*L/W) | −5.4 | −4.8 | −7.3 | −7.3 | −5.8 | −19 |
| | Vth [V] | | | | | | |
| | Mobility | 1.7 | 1.6 | 1.3 | 1.2 | 2.0 × 10⁻³ | 2.8 × 10⁻³ |
| | [cm² v⁻¹ s⁻¹] | | | | | | |
| Saturation | Normalised | 7.7 × 10⁻⁷ | 7.6 × 10⁻⁷ | 4.8 × 10⁻⁷ | 4.6 × 10⁻⁷ | 1.3 × 10⁻⁹ | 9.0 × 10⁻¹⁰ |
| (Vd = −20 V) | Ion [A] | | | | | | |
| | (Ion*L/W) | −4.7 | −4.5 | −7.3 | −7.3 | −5.4 | −5.6 |
| | Vth [V] | | | | | | |
| | Mobility | 2 | 1.9 | 1.8 | 1.7 | 5.1 × 10⁻³ | 3.5 × 10⁻³ |
| | [cm² V⁻¹ s⁻¹] | | | | | | |

Other parameters are also critical to OTFT performance. For example, a small threshold-voltage is desirable for low power operation. The performance parameters for OTFTs based on the three polymers are presented in Table 2. The threshold voltage (Vₜₕ) is the voltage at which charge accumulation in the OTFT is sufficient that the channel becomes conductive. Vₜₕ is therefore associated with the presence of deep trap states which are not able to contribute to charge transport. A small Vₜₕ indicates a low trap state density and minimal energetic disorder.^{[21]} The IDT-BS OTFTs exhibited a smaller average Vₜₕ in both the linear and saturation regime compared with OTFTs based on the other two polymers. This indicates that energetic disorder of IDT-BS is reduced compared with IDT-BT and IDT-BO as a result of enhanced backbone rigidity due to stronger intramolecular short-contacts.

In summary, a series of indaceno[1,2-b:5,6-'b]dithiophene (IDT)-based polymers with the chalcogen atom of the acceptor monomer varied from oxygen to selenium have been prepared. The short-contact interaction between the IDT peripheral hydrogen and nitrogen of the BT unit was shown to be enhanced by changing the chalcogen atom of the acceptor unit from oxygen, sulphur and selenium. This enhancement was shown to benefit both the structural order of the polymers in thin-films as well as their performance in organic thin film transistors, leading to higher mobility values. This work provides experimental support for the key role that short-contact interactions play in the performance of D-A polymers and thereby gives new insight into how to rationally design semiconducting materials with high mobilities.

While specific embodiments of the invention have been described herein for the purpose of reference and illustration, various modifications will be apparent to a person skilled in the art without departing from the scope of the invention as defined by the appended claims.

### REFERENCES

[1] H. Sirringhaus, Adv. Mater. 2014, 26, 1319.
[2] A. F. Paterson, S. Singh, K. J. Fallon, T. Hodsden, Y. Han, B. C. Schroeder, H. Bronstein, M. Heeney, I. McCulloch, T. D. Anthopoulos, Adv. Mater. 2018, 30, 1.
[3] H. Chen, M. Hurhangee, M. Nikolka, W. Zhang, M. Kirkus, M. Neophytou, S. J. Cryer, D. Harkin, P. Hayoz, M. Abdi-Jalebi, C. R. McNeill, H. Sirringhaus, I. McCulloch, Adv. Mater. 2017, 29, 1702523.
[4] H. Chen, A. Wadsworth, C. Ma, A. Nanni, W. Zhang, M. Nikolka, A. M. T. Luci, L. M. A. Perdigão, K. J. Thorley, C. Cendra, B. Larson, G. Rumbles, T. D. Anthopoulos, A. Salleo, G. Costantini, H. Sirringhaus, I. McCulloch, J. Am. Chem. Soc. 2019, 141, 18806.
[5] A. Wadsworth, H. Chen, K. J. Thorley, C. Cendra, M. Nikolka, H. Bristow, M. Moser, A. Salleo, T. D. Anthopoulos, H. Sirringhaus, I. McCulloch, J. Am. Chem. Soc. 2020, 142, 652.
[6] S. Fratini, M. Nikolka, A. Salleo, G. Schweicher, H. Sirringhaus, Nat. Mater. 2020, 19, 491.
[7] R. Noriega, J. Rivnay, K. Vandewal, F. P. V. Koch, N. Stingelin, P. Smith, M. F. Toney, A. Salleo, Nat. Mater. 2013, 12, 1038.
[8] W. Zhang, J. Smith, S. E. Watkins, R. Gysel, M. Mcgehee, A. Salleo, J. Kirkpatrick, S. Ashraf, T. Anthopoulos, M. Heeney, J. Am. Chem. Soc. 2010, 132, 11437.
[9] M. Nikolka, K. Broch, J. Armitage, D. Hanifi, P. J. Nowack, D. Venkateshvaran, A. Sadhanala, J. Saska, M. Mascal, S. H. Jung, J. K. Lee, I. McCulloch, A. Salleo, H. Sirringhaus, Nat. Commun. 2019, 10, 1.
[10] P. Sonar, S. P. Singh, Y. Li, M. S. Soh, A. Dodabalapur, Adv. Mater. 2010, 22, 5409.
[11] M. Gruber, S.-H. Jung, S. Schott, D. Venkateshvaran, A. J. Kronemeijer, J. W. Andreasen, C. R. McNeill, W. W. H. Wong, M. Shahid, M. Heeney, J.-K. Lee, H. Sirringhaus, Chem. Sci. 2015, 6, 6949.
[12] M. Nikolka, M. Hurhangee, A. Sadhanala, H. Chen, I. McCulloch, H. Sirringhaus, Adv. Electron. Mater. 2018, 4, 1700410.
[13] H. Bronstein, D. S. Leem, R. Hamilton, P. Woebkenberg, S. King, W. Zhang, R. S. Ashraf, M. Heeney, T. D. Anthopoulos, J. De Mello, I. McCulloch, Macromolecules 2011, 44, 6649.
[14] Y. Zhang, S. C. Chien, K. S. Chen, H. L. Yip, Y. Sun, J. A. Davies, F. C. Chen, A. K. Y. Jen, Chem. Commun. 2011, 47, 11026.
[15] L. C. Karabay, B. Karabay, M. S. Karakoy, A. Cihaner, J. Electroanal. Chem. 2016, 780, 84.
[16] J. Lee, D. H. Sin, J. A. Clement, C. Kulshreshtha, H. G. Kim, E. Song, J. Shin, H. Hwang, K. Cho, Macromolecules 2016, 49, 9358.
[17] M. Planells, B. C. Schroeder, I. McCulloch, Macromolecules 2014, 47, 5889.
[18] M. Jeffries-EL, B. M. Kobilka, B. J. Hale, Macromolecules 2014, 47, 7253.
[19] J. Hou, M.-H. Park, S. Zhang, Y. Yao, L.-M. Chen, J.-H. Li, Y. Yang, Macromolecules 2008, 41, 6012.
[20] C. Liu, G. Li, R. Di Pietro, J. Huang, Y.-Y. Noh, X. Liu, T. Minari, Phys. Rev. Appl. 2017, 8, 034020.
[21] S. Hunter, J. Chen, T. D. Anthopoulos, Adv. Funct. Mater. 2014, 24, 5969.
[22] W. Zhang, J. Smith, S. E. Watkins, R. Gysel, M. McGehee, A. Salleo, J. Kirkpatrick, S. Ashraf, T. Anthopoulos, M. Heeney, I. McCulloch, J. Am. Chem. Soc. 2010, 132, 11437.
[23] G. L. Gibson, T. M. McCormick, D. S. Seferos, J. Phys. Chem. C 2013, 117, 16606.
[24] R. Yang, R. Tian, Q. Hou, W. Yang, Y. Cao, Macromolecules 2008, 41, 8951.
[25] N. E. Jackson, B. M. Savoie, K. L. Kohlstedt, M. Olvera de la Cruz, G. C. Schatz, L. X. Chen, M. A. Ratner, J. Am. Chem. Soc. 2013, 135, 10475.
[26] D. Venkateshvaran, M. Nikolka, A. Sadhanala, V. Lemaur, M. Zelazny, M. Kepa, M. Hurhangee, A. J. Kronemeijer, V. Pecunia, I. Nasrallah, I. Romanov, K. Broch, I. McCulloch, D. Emin, Y. Olivier, J. Cornil, D. Beljonne, H. Sirringhaus, Nature 2014, 515, 384.
[27] H. Huang, L. Yang, A. Facchetti, T. J. Marks, Chem. Rev. 2017, 117, 10291.

1. A compound comprising a unit of formula (I): 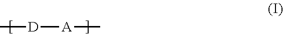
wherein
D is a collinear, π-electron rich group of formula (II) 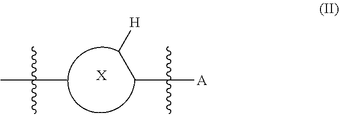
wherein:
X is a polycyclic, π-conjugated, ring system; and
A is a collinear, π-electron deficient group of formula (III): 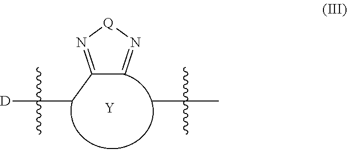
wherein:
Q is selenium or tellurium; and
Y is a monocyclic or polycyclic, π-conjugated, ring system:

2. The compound of claim 1, wherein Y is:
a monocyclic, π-conjugated ring system, being a 6-membered aromatic or heteroaromatic ring; or
a polycyclic, π-conjugated ring system, being a ring system comprising 5-or 6-membered aromatic or heteroaromatic fused rings.

3. The compound of claim 1 or 2, wherein when Y is a polycyclic, π-conjugated ring system, one or more (but not all) of the rings may have a structure according to formula (IV): 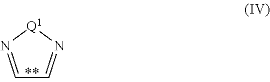
wherein:
Q¹ is oxygen, sulfur, selenium or tellurium; and
** denotes the bond shared with the one or more π-conjugated rings.

4. The compound of claim 1, wherein A is a collinear, π-electron-accepting group of formula (IIIa), (IIIb), (IIIc) or (IIId): 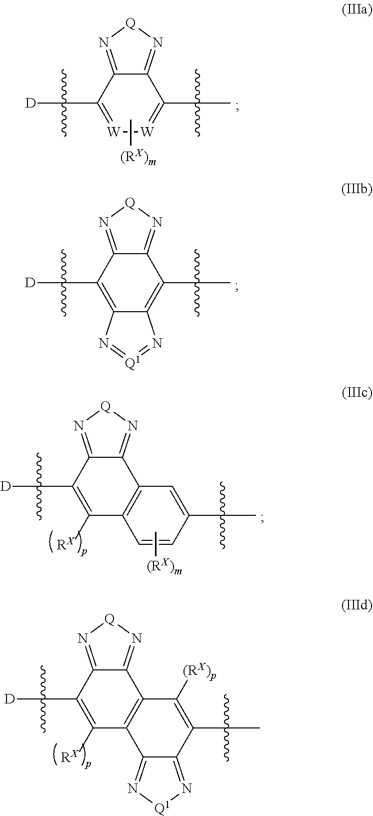
wherein:
Q is selenium or tellurium;
each W is nitrogen or carbon;
each R^{X} is independently selected from the group consisting of nitro, cyano, halo, alkyl, haloalkyl, alkoxy and haloalkoxy;
Q¹ is oxygen, sulfur, selenium or tellurium;
when Wis nitrogen, m is 0, and when Wis carbon, m is 0, 1 or 2;
each p is independently 0 or 1; and
q is 0, 1, 2 or 3.

5. The compound of claim 4, wherein m is 0, 1 or 2, and p and q are 0.

6. The compound of claim 4 or 5, wherein Q and Q¹ are selenium.

7. The compound of claim 4, 5 or 6, wherein R^{X} is selected from the group consisting of nitro, cyano, fluoro, (1-3C) alkoxy, (1-3C) fluoroalkyl and (1-3C) alkyl; and all R^{X} are identical.

8. The compound of any one of the preceding claims, wherein A is a collinear, π-electron deficient group of formula (IIIa-i), (IIIa-ii), (IIIa-iii), (IIIa-iv), (IIIa-v), (IIIa-vi) or (IIIa-vii): 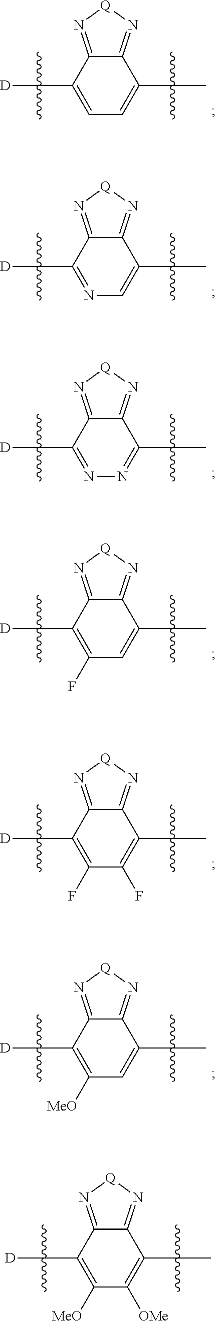
wherein Q has any of those definitions recited in any preceding claim.

9. The compound of any one of the preceding claims, wherein A is 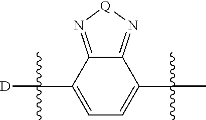
wherein Q has any of those definitions recited in any preceding claim.

10. The compound of any one of the preceding claims, wherein X comprises a plurality of fused, 5-and/or 6-membered, π-conjugated rings.

11. The compound of any one of the preceding claims, wherein D is a collinear, π-electron rich group of formula (IIa): 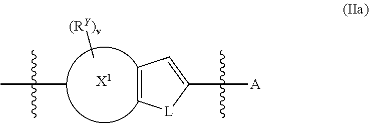
wherein:
X1 is a monocyclic or polycyclic π-conjugated ring system;
Each R^{Y} is independently selected from the group consisting of hydroxy, cyano, halo, alkyl, alkenyl and alkynyl, optionally wherein one or more carbon atom in the alkyl, alkenyl and alkynyl group is replaced by a heteroatom;
v is 0, 1, 2, 3, 4, 5 or 6; and
L is sulfur, oxygen, nitrogen or selenium.

12. The compound of any one of the preceding claims, wherein D is a collinear, π-electron rich group of formula (IIb): 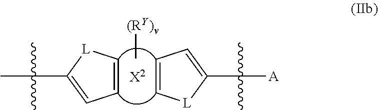
wherein:
X² is absent, or is a monocyclic or polycyclic π-conjugated ring system;
each R^{Y} is independently selected from the group consisting of hydroxy, cyano, halo, alkyl, alkenyl and alkynyl, optionally wherein one or more carbon atom in the alkyl, alkenyl and alkynyl group is replaced by a heteroatom;
v is 0, 1, 2, 3, 4, 5 or 6; and
each L is independently sulfur, oxygen, nitrogen or selenium.

13. The compound of claim 12, wherein X² is:
absent;
a monocyclic π-conjugated ring system; or
a polycyclic, π-conjugated ring system having 2-13 rings.

14. The compound of claim 11, 12 or 13, wherein L is sulfur; each R^{Y} is independently selected from the group consisting of alkyl or a polyethylene glycol group; and v is 0, 1, 2, 3 or 4.

15. The compound of any one of claims 11 to 14, wherein R^{Y} is selected from the group consisting of alkyl; and all R^{Y} are identical.

16. The compound of any one of the preceding claims, wherein D is a collinear, π-electron rich group selected from the group consisting of thioenothiophene (TT), thieno[2′,3′:4,5]thieno[3,2-b]thieno[2,3-d]thiophene (TTTT), indacenodithiophene (IDT), indacenodithieno[3,2-b]dithiophene (IDTT), indacenodithieno[3,2-b:2′,3′-d]thiophene (IDTTT), indacenodithieno[3,2-b]dibenzo[1,2-b:4,5-b′]thiophene (TBIDT), indacenodithienodinaphtho [2,3-b:6,7-b′]thiophene (TNIDT), indacenodithienodibenzo[b]thieno[2,3-d]thiophene (TTBIDT), indacenodithienodithieno[2′,3′:4,5]thieno[3,2-b]thieno[2,3-d]thiophene (IDTTTT), indacenodithienodithieno[2,3-d]benzo[1,2-b:4,5-b′]thiophene (TBTIDT), dithieno[3,2-b]indenofluorene (TIF); dithieno[2,3-d]thienoindenofluorene (TTIF), dithienobenzo[1,2-b:4,5-b′]indenofluorene (TBIF), dithienonaphtho [1,2-b:4,5-b′]indenofluorene (TBBIF), dithieno[2,3-d]thienodibenzo[1,2-b:4,5-b′]indenofluorene (TTBIF), dithienodithieno[2′,3′:4,5]thieno[3,2-b]thieno[2,3-d]thienoindenofluorene (TTTIF) and dithieno[2,3-d]benzo[1,2-b:4,5-b′]thienoindenofluorene (TBTTIF), any one of which is optionally substituted with one or more R^{Y}.

17. The compound of any one of the preceding claims, wherein D is a collinear, π-electron rich group selected from the group consisting of indacenodithiophene (IDT), dithieno[3,2-b]indenofluorene (TIF), indacenodithieno[3,2-b]dibenzo[1,2-b:4,5-b′]thiophene (TBIDT) and dithieno[2,3-d]thienoindenofluorene (TTIF), any one of which is optionally substituted with one or more R^{Y}.

18. The compound of any one of the preceding claims, wherein D is indacenodithiophene (IDT) optionally substituted with one or more R^{Y}.

19. The compound of any one of the preceding claims, wherein A is: 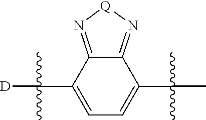
and D is indacenodithiophene (IDT) optionally substituted with one or more R^{Y} as defined any preceding statement.

20. The compound of any one of the preceding claims, wherein the compound comprises a plurality of units of formula (I).

21. The compound of any one of the preceding claims, wherein the compound is a polymer or an oligomer.

22. The compound of any one of the preceding claims, wherein the compound is semiconductive.

23. An electronic device or component comprising a compound or polymer of any one of the preceding claims.

24. The electronic device of component of claim 23, wherein the electronic device or component is a transistor.

25. Use of a compound as defined in any one of the preceding claims as a semiconducting material.
